(19) United States
(12) Patent Application Publication
(10) Pub. No.: US 2025/0046707 A1
(43) Pub. Date: Feb. 6, 2025

(54) SEMICONDUCTOR DEVICE INCLUDING TAPERED DIELECTRIC LAYER AND METHOD OF FORMING THE SAME

(71) Applicant: SK hynix Inc., Gyeonggi-do (KR)

(72) Inventors: Beom Ho MUN, Gyeonggi-do (KR); Ju Min LEE, Gyeonggi-do (KR); Bo Sung KIM, Gyeonggi-do (KR); Jin Yul LEE, Gyeonggi-do (KR)

(21) Appl. No.: 18/531,710

(22) Filed: Dec. 7, 2023

(30) Foreign Application Priority Data
Aug. 1, 2023 (KR) 10-2023-0100367

(51) Int. Cl. H01L 23/528; H10B 12/00

(52) U.S. Cl. CPC H01L 23/528; H10B 12/315; H10B 53/00; H10B 61/00; H10B 63/00; H10B 63/10

(57) ABSTRACT

A semiconductor device may include a plurality of active regions delimited on a substrate. A plurality of bit line structures crossing over the plurality of the active regions may be provided. A plurality of storage node contacts may be disposed between the plurality of the bit line structures. A plug isolation pattern may be disposed between the plurality of the storage node contacts. The plug isolation pattern may include an isolation insulating layer between the plurality of the storage node contacts; and a tapered dielectric layer between the isolation insulating layer and the plurality of the storage node contacts.

### CROSS-REFERENCE TO RELATED APPLICATION

The present application claims priority under 35 U.S.C. § 119 (a) to Korean Patent Application No. 10-2023-0100367 filed on Aug. 1, 2023, which is incorporated herein by reference in its entirety.

### BACKGROUND

### 1. Technical Field

Various embodiments of the present disclosure generally relate to a semiconductor device including a tapered dielectric layer and a method of forming the same.

### 2. Related Art

With the high integration of semiconductor devices, the spacing between interconnects is getting narrower. A plurality of horizontal interconnect structures and a plurality of vertical interconnect structures may be disposed in an insulating layer. A reduction in the spacing between the plurality of horizontal/vertical interconnect structures increases leakage current and causes interference between the interconnect structures.

### SUMMARY

Various embodiments of the present disclosure are directed to a semiconductor device which prevents interference and leakage current between a plurality of interconnection structures and is advantageous for high integration. Various embodiments of the present disclosure are also directed to a method of forming the semiconductor device.

According to an embodiment of the present disclosure, a semiconductor device may include a plurality of active regions delimited on a substrate. A plurality of bit line structures crossing over the plurality of the active regions may be provided. A plurality of storage node contacts may be disposed between the plurality of the bit line structures. A plug isolation pattern may be disposed between the plurality of the storage node contacts. The plug isolation pattern may include an isolation insulating layer between the plurality of the storage node contacts; and a tapered dielectric layer between the isolation insulating layer and the plurality of the storage node contacts.

In an embodiment of the present disclosure, a semiconductor device may include a plurality of interconnect structures disposed on a substrate and spaced apart from each other. Each contact plug of a plurality of contact plugs may be disposed between a corresponding pair of adjacent interconnect structures. A plug isolation pattern may be disposed between the plurality of contact plugs. The plug isolation pattern may include an isolation insulating layer between the plurality of contact plugs; and a tapered dielectric layer between the isolation insulating layer and the plurality of contact plugs.

According to the embodiments of the disclosed technology, a plurality of storage node contacts and a plurality of plug isolation patterns disposed between a plurality of bit line structures may be provided. The plug isolation pattern may include an isolation insulating layer and a tapered dielectric layer. The tapered dielectric layer may play a role of preventing a seam from being formed in the isolation insulating layer. The tapered dielectric layer may play a role of preventing a defect such as a Y-bridge. The tapered dielectric layer may play a role of improving hydrogen passivation characteristics and row hammer characteristics. It is possible to implement a semiconductor device which prevents interference and leakage current between a plurality of interconnection structures and is advantageous for high integration.

These and other features and advantages of the present disclosure may be better understood from the following figures and detailed description.

### BRIEF DESCRIPTION OF THE DRAWINGS

FIG. 1 is a cross-sectional view illustrating a semiconductor device based on an embodiment of the disclosed technology.

FIGS. 2 to 5 are partial views showing a portion of FIG. 1.

FIG. 6 is a layout diagram illustrating the semiconductor device based on an embodiment of the present disclosure.

FIG. 7 is a layout diagram omitting some components of FIG. 6.

FIGS. 8 to 22 are cross-sectional views illustrating a method of forming the semiconductor device based on an embodiment of the present disclosure.

### DETAILED DESCRIPTION

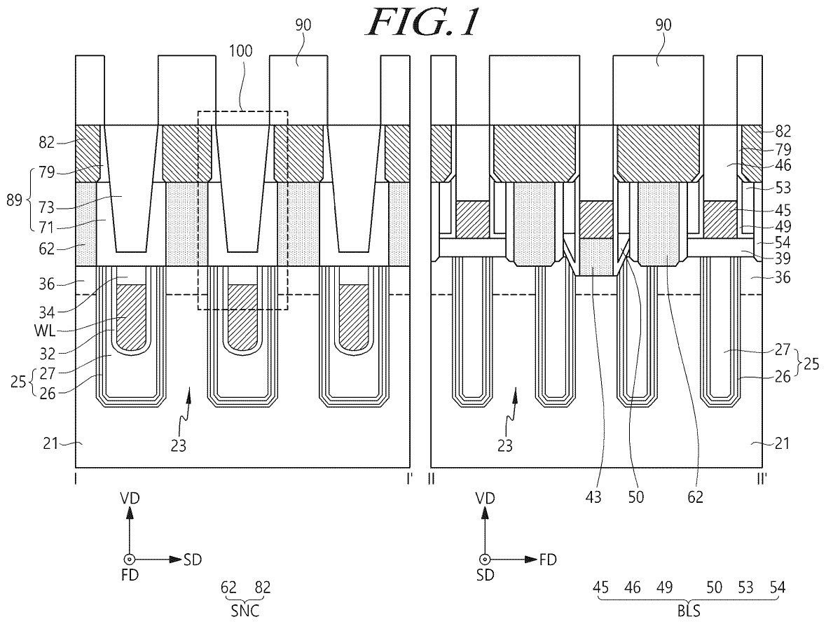

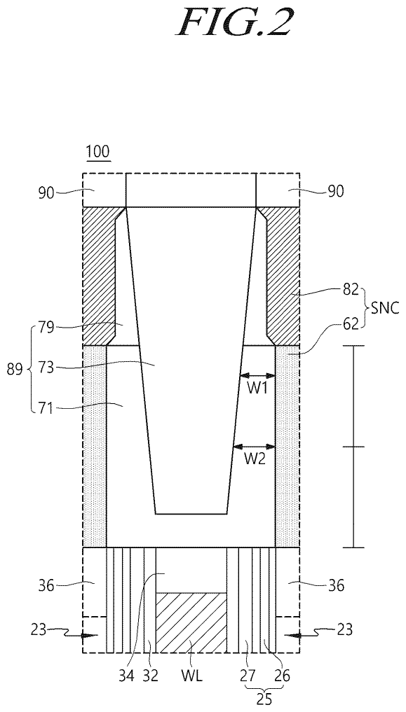

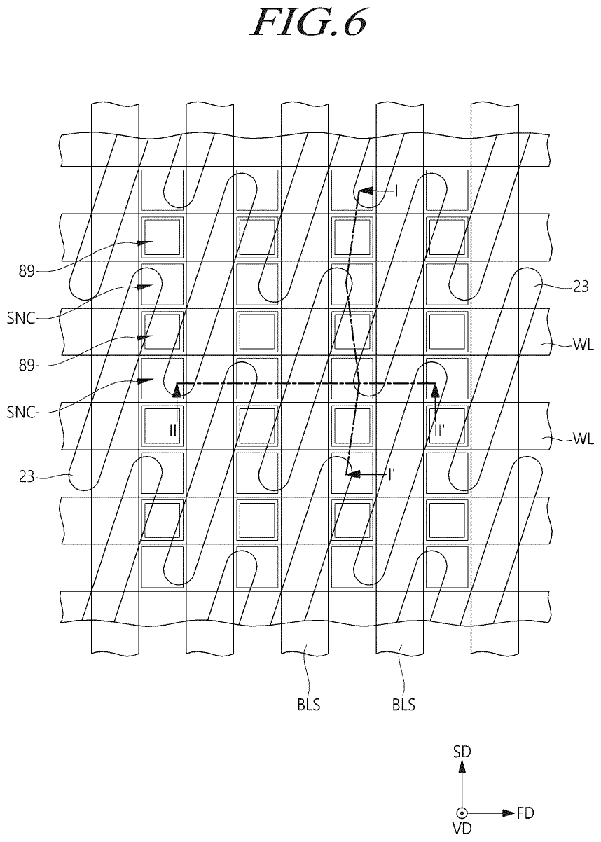

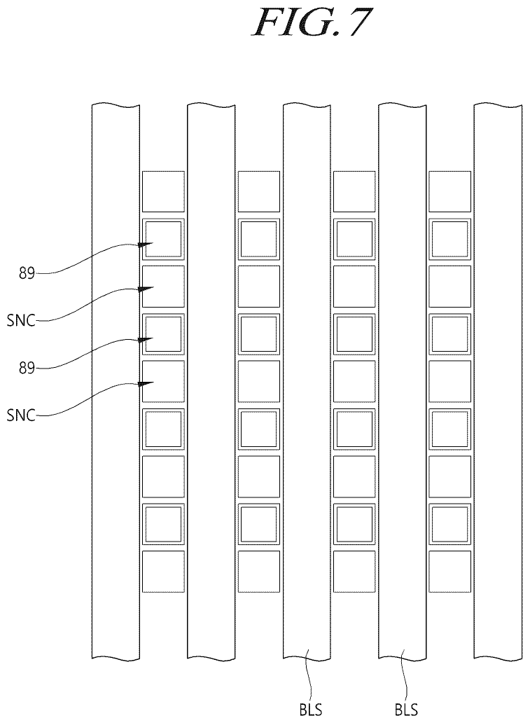

FIG. 1 is a cross-sectional view illustrating a semiconductor device based on an embodiment of the present disclosure, and FIGS. 2 to 5 are partial views showing a portion 100 of FIG. 1. FIG. 6 is a layout diagram illustrating the semiconductor device based on an embodiment of the present disclosure, and FIG. 7 is a layout diagram omitting some components of FIG. 6. FIG. 1 may be a cross-sectional view taken along the lines I-I′ and II-II′ of FIG. 6. In an embodiment, the semiconductor device based on an embodiment of the present disclosure may include a memory device such as the cell array of a dynamic random access memory (DRAM).

Referring to FIG. 1, the semiconductor device based on an embodiment of the present disclosure may include a substrate 21, a plurality of active regions 23, an isolation layer 25, a gate dielectric layer 32, a plurality of word lines WL, a gate capping layer 34, a plurality of source/drain regions 36, an interlayer insulating layer 39, a bit plug 43, a plurality of bit lines 45, a bit capping layer 46, a first spacer 49, a gap-fill spacer 50, a second spacer 53, a third spacer 54, a plurality of lower contact plugs 62, a tapered dielectric layer 71, an isolation insulating layer 73, an upper spacer 79, a plurality of upper contact plugs 82, and a plurality of memory elements 90.

The plurality of bit lines 45, the bit capping layer 46, the first spacer 49, the gap-fill spacer 50, the second spacer 53 and the third spacer 54 may configure a plurality of bit line structures BLS. The plurality of lower contact plugs 62 and the plurality of upper contact plugs 82 may configure a plurality of storage node contacts SNC. The tapered dielectric layer 71, the isolation insulating layer 73 and the upper spacer 79 may configure a plurality of plug isolation patterns 89. In an embodiment, the plurality of the bit line structures BLS may be referred to as a plurality of interconnect structures. The plurality of the storage node contacts SNC may be referred to as a plurality of contact plugs.

A first direction FD, a second direction SD and a third direction VD may be defined. The second direction SD may cross the first direction FD. The third direction VD may cross the first direction FD and the second direction SD. In an embodiment, the first direction FD and the second direction SD may be parallel to the upper surface and lower surface of the substrate 21. The third direction VD may be perpendicular to the upper surface and lower surface of the substrate 21. The second direction SD may be perpendicular to the first direction FD. The third direction VD may be perpendicular to the first direction FD and the second direction SD.

Referring to FIGS. 1 and 6, the isolation layer 25 which delimits the plurality of the active regions 23 may be disposed in the substrate 21. The plurality of the active regions 23 may be spaced apart from each other in the first direction FD and the second direction SD. The plurality of the word line structures may be disposed to cross the plurality of the active regions 23 and extend in the isolation layer 25. The gate capping layer 34 may be disposed on the plurality of the word line structures. The gate dielectric layer 32 may be disposed to surround the side and lowermost (bottom) surfaces of the plurality of the word line structures. The plurality of the word line structures may be disposed at a lower level than the upper surfaces of the plurality of the active regions 23 in the third direction VD. The plurality of source/drain regions 36 may be disposed adjacent to the plurality of the word line structures in the plurality of the active regions 23 adjacent to the plurality of the word line structures.

The interlayer insulating layer 39 may be disposed on the isolation layer 25, the gate capping layer 34 and the plurality of source/drain regions 36. At least one bit plug 43 may be disposed to contact the plurality of source/drain regions 36 by passing through the interlayer insulating layer 39. Each of the plurality of the active regions 23 may be electrically connected to the at least one bit plug 43 through a corresponding source/drain region 36.

The plurality of the bit line structures BLS which cross over the plurality of the active regions 23 may be disposed on the interlayer insulating layer 39. Each of the plurality of the bit line structures BLS may include the bit line 45 and the bit capping layer 46 formed on the bit line 45. The bit capping layer 46 may cover at least part of or the entire top (or uppermost) surface of the bit line 45i. The bit line 45 may contact the at least one bit plug 43. The bit line 45 may be formed over at least one bit plug 43 and may cover at least part of or the entire top surface of the bit plug 43.

The first spacer 49 may be disposed on the side surfaces of the bit line 45 and the bit capping layer 46, and may extend onto the side surfaces of the bit plug 43 and the interlayer insulating layer 39. The gap-fill spacer 50 may be disposed on the first spacer 49 adjacent to the side surfaces of the bit plug 43. The first spacer 49 may extend between the gap-fill spacer 50 and the isolation layer 25. The second spacer 53 may be disposed on the first spacer 49. The side surfaces of the second spacer 53 may contact the side surfaces of the first spacer 49. The bottom surface of the second spacer 53 may contact the first spacer 49. The first spacer 49 may include an L-shape. The second spacer 53 may contact the upper surface of the gap-fill spacer 50.

The third spacer 54 may be disposed on the second spacer 53. The side surfaces of the third spacer 54 may contact the side surfaces of the second spacer 53. The third spacer 54 may extend into the plurality of source/drain regions 36 by passing through the interlayer insulating layer 39. The side surfaces of the third spacer 54 may contact the first spacer 49 and the interlayer insulating layer 39. The lowermost surface (or bottom surface) of the third spacer 54 may be disposed at a lower level than the uppermost surface (or top surface) of the plurality of source/drain regions 36 in the third direction VD.

In an embodiment, the second spacer 53 may be disposed on the outer surface of the first spacer 49. The first spacer 49 may be disposed between the second spacer 53 and the plurality of bit lines 45 and between the second spacer 53 and the bit capping layer 46. The third spacer 54 may be disposed on the outer surface of the second spacer 53. The second spacer 53 may be disposed between the third spacer 54 and the first spacer 49. The gap-fill spacer 50 may be surrounded by the first spacer 49, the second spacer 53 and the third spacer 54.

The plurality of the storage node contacts SNC and the plurality of the plug isolation patterns 89 may be disposed between the plurality of the bit line structures BLS. Each of the plurality of the plug isolation patterns 89 may be disposed between the plurality of the storage node contacts SNC.

Each of the plurality of the storage node contacts SNC may include the lower contact plug 62 which contacts a corresponding source/drain region among the plurality of source/drain regions 36 in the plurality of the active regions 23, and the upper contact plug 82 which contacts the lower contact plug 62. The lower contact plug 62 may be aligned on top of a corresponding active region among the plurality of the active regions 23 in the third direction VD. At least a portion of the lower contact plug 62 may overlap with the upper portion of a corresponding active region among the plurality of the active regions 23. The horizontal width of the upper contact plug 82 may be larger than the horizontal width of the lower contact plug 62.

The lowermost surface (or bottom surface) of the lower contact plug 62 may be disposed at a lower level than the uppermost surface (or top surface) of the plurality of source/drain regions 36 in the third direction VD. The lowermost surface (or bottom surface) of the lower contact plug 62 may be disposed at a lower level than the lowermost surface (or bottom surface) of the third spacer 54 in the third direction VD. The uppermost surface (or top surface) of the lower contact plug 62 may be disposed at a higher level than the upper surfaces of adjacent bit lines 45 in the third direction VD.

The plurality of the plug isolation patterns 89 may overlap with the plurality of the word lines WL and the gate capping layer 34. The isolation insulating layer 73 may be disposed between the plurality of the storage node contacts SNC. The tapered dielectric layer 71 may surround the side surfaces and bottom surface of the isolation insulating layer 73. The uppermost surface (or top surface) of the tapered dielectric layer 71 may be disposed at a lower level than the upper surface of the isolation insulating layer 73 in the third direction VD. The upper spacer 79 may be disposed on the tapered dielectric layer 71, and may surround the side surfaces of the isolation insulating layer 73. The upper spacer 79 may be disposed between the isolation insulating layer 73 and the upper contact plug 82. The upper spacer 79 may extend between the bit capping layer 46 and the upper contact plug 82.

The tapered dielectric layer 71 may extend between the isolation insulating layer 73 and the lower contact plug 62. The horizontal width of the tapered dielectric layer 71 in the second direction SD may gradually increase from a top surface to a bottom surface. The isolation insulating layer 73 may include an inverted trapezoid shape whose horizontal width gradually increases from a bottom surface to a top surface. In an embodiment, the isolation insulating layer 73 may include a material which has an etch selectivity with respect to the tapered dielectric layer 71. The isolation insulating layer 73 may include nitride, and the tapered dielectric layer 71 may include oxide. The tapered dielectric layer 71 may extend between the isolation insulating layer 73 and the gate capping layer 34 and between the isolation insulating layer 73 and the isolation layer 25. The uppermost surface (or top surface) of the tapered dielectric layer 71 may be disposed at a higher level than the upper surface of the bit line 45 in the third direction VD.

The plurality of memory elements 90 may be disposed on the plurality of the storage node contacts SNC. Each of the plurality of memory elements 90 may include a cell capacitor of a DRAM, a magnetic tunneling junction (MTJ) of a magnetoresistive random access memory (MRAM), a phase-change random access memory (PRAM), a ferroelectric random access memory (FRAM), a resistive random access memory (RRAM), or a combination thereof. In an embodiment, when each of the plurality of memory elements 90 includes the cell capacitor of a DRAM, the cell capacitor may include a capacitor dielectric layer between first and second electrodes. The first electrode of the cell capacitor may be referred to as a storage node. The storage node may be connected to the plurality of the storage node contacts SNC. The storage node may include a pillar shape, a cylinder shape, a box shape, or a combination thereof.

According to an embodiment of the present disclosure, the tapered dielectric layer 71 may mitigate and/or prevent formation of a seam in the isolation insulating layer 73. In an embodiment, when the formation of a seam is not completely suppressed, the tapered dielectric layer 71 may play a role of mitigating the formation of a seam. For example, a relatively small seam may be formed in the isolation insulating layer 73 but the tapered dielectric layer 71 may prevent the small seam to turn into a defect such as a Y-bridge. Moreover, the tapered dielectric layer 71 may improve the hydrogen passivation characteristics and the row hammer characteristics of the semiconductor.

Referring to FIGS. 1 and 2, according to an embodiment, the upper surfaces of the tapered dielectric layer 71 and the lower contact plug 62 may lie substantially at the same plane. The horizontal width of the tapered dielectric layer 71 may gradually increase from a top surface to a bottom surface. The tapered dielectric layer 71 may have a first horizontal width W1 between the lower contact plug 62 and the isolation insulating layer 73 in the second direction SD at a position of 85% of a total vertical height from the bottom thereof in the third direction VD. The tapered dielectric layer 71 may have a second horizontal width W2 between the lower contact plug 62 and the isolation insulating layer 73 in the second direction SD at a position of 50% of the total vertical height in the third direction VD. The second horizontal width W2 may be larger than the first horizontal width W1.

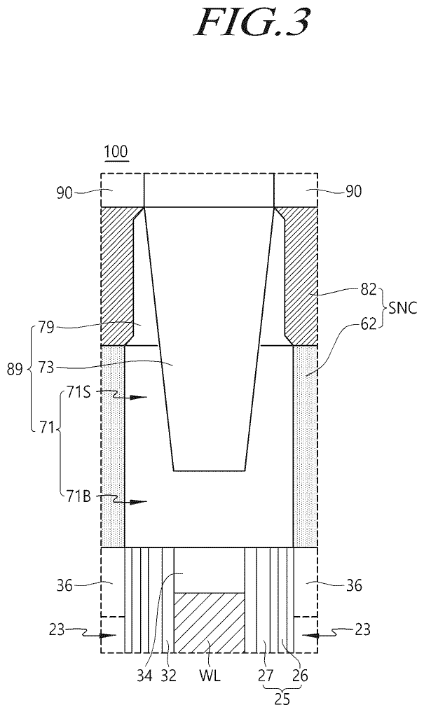

Referring to FIG. 3, the tapered dielectric layer 71 may surround the side surfaces and bottom surface of the isolation insulating layer 73. The tapered dielectric layer 71 may include a bottom portion 71B and a side portion 71S. The bottom portion 71B of the tapered dielectric layer 71 may extend between the isolation insulating layer 73 and the gate capping layer 34. The side portion 71S of the tapered dielectric layer 71 may extend between the isolation insulating layer 73 and the lower contact plug 62. In an embodiment, the thickness of the bottom portion 71B in the third direction VD may be larger than the horizontal width of the side portion 71S in the second direction SD.

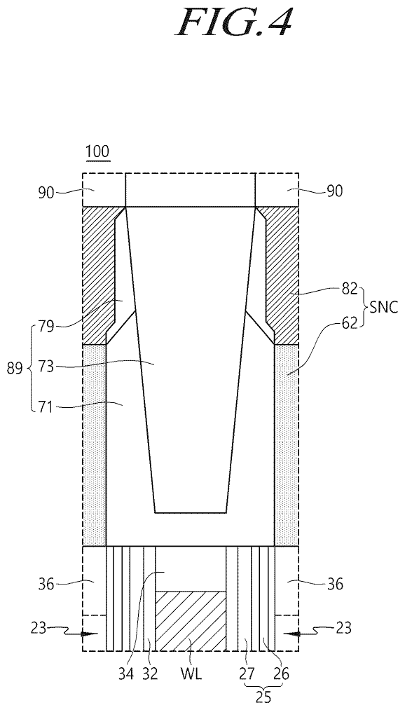

Referring to FIG. 4, in an embodiment, the uppermost surface (or top surface) of the tapered dielectric layer 71 may protrude to a higher level than the upper surface of the lower contact plug 62 in the third direction VD.

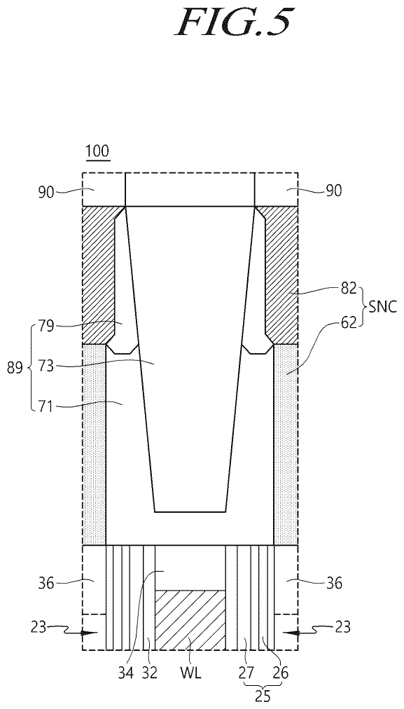

Referring to FIG. 5, in an embodiment, the upper surface of the tapered dielectric layer 71 may be recessed to a lower level than the upper surface of the lower contact plug 62 in the third direction VD.

Referring to FIG. 6, the semiconductor device based on an embodiment of the present disclosure may include the plurality of the active regions 23, the plurality of the word line structures, the plurality of the bit line structures BLS, the plurality of the storage node contacts SNC, and the plurality of the plug isolation patterns 89.

The plurality of the word line structures may cross the plurality of the active regions 23. Each of the plurality of the word line structures may extend in the first direction FD. The plurality of the word line structures may be arranged parallel to each other in the second direction SD. In an embodiment, a corresponding two word line structures among the plurality of the word line structures may cross each of the plurality of the active regions 23.

Each of the plurality of the bit line structures BLS may extend in the second direction SD. The plurality of the bit line structures BLS may be arranged parallel to each other in the first direction FD. The plurality of the bit line structures BLS may cross over the plurality of the active regions 23. Each of the plurality of the bit line structures BLS may cross over the plurality of the word line structures. Each of the plurality of the bit line structures BLS may be orthogonal to the plurality of the word line structures. In an embodiment, a corresponding bit line structure among the plurality of the bit line structures BLS may cross each of the plurality of the active regions 23.

The plurality of the storage node contacts SNC and the plurality of the plug isolation patterns 89 may be disposed between the plurality of the bit line structures BLS. The plurality of the storage node contacts SNC may overlap with the plurality of the active regions 23. The plurality of the plug isolation patterns 89 may overlap with the plurality of the word line structures.

Referring to FIGS. 6 and 7, the plurality of the storage node contacts SNC and the plurality of the plug isolation patterns 89 may be disposed between the plurality of the bit line structures BLS. For example, a plurality of the storage node contacts SNC and a plurality of the plug isolation patterns 89 may be alternately and repeatedly disposed in the second direction SD between a pair of the bit line structures BLS.

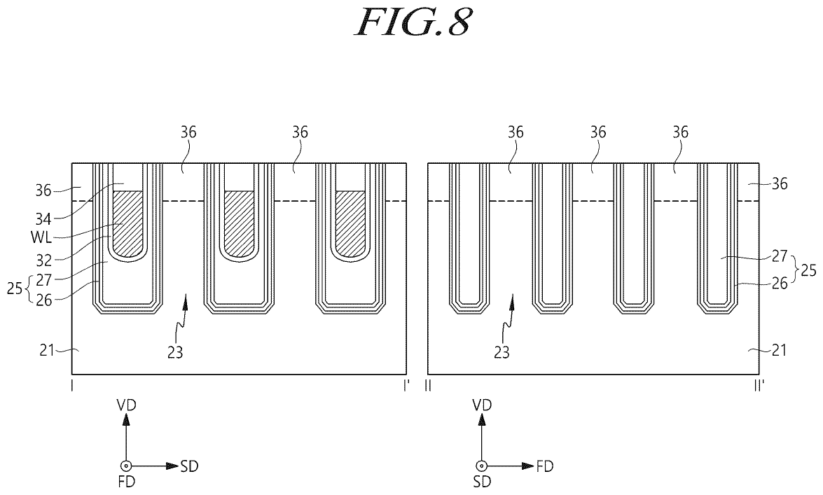

FIGS. 8 to 22 are cross-sectional views illustrating a method of forming the semiconductor device based on an embodiment of the present disclosure. FIGS. 8 to 22 are cross-sectional views taken along the lines I-I and II-II of FIG. 6.

Referring to FIGS. 6 and 8, an isolation layer 25 which delimits a plurality of active regions 23 may be formed in a substrate 21. Also, a gate dielectric layer 32 and a plurality of word lines WL may be formed crossing the plurality of the active regions 23 and extending in the isolation layer 25. Also, a gate capping layer 34 may be formed on the plurality of the word line structures. A plurality of source/drain regions 36 may be formed in the plurality of the active regions 23.

The substrate 21 may include a semiconductor substrate such as a silicon wafer or a silicon on insulator (SOI) wafer. The substrate 21 may include a III-V group semiconductor substrate, for example, a compound semiconductor substrate such as GaAs. The substrate 21 may include monocrystalline silicon, polysilicon, amorphous silicon, monocrystalline silicon germanium, polycrystalline silicon germanium, carbon-doped silicon, or a combination thereof.

The plurality of the active regions 23 and the isolation layer 25 may be formed using a trench isolation technology such as shallow trench isolation (STI). In an embodiment, the plurality of the active regions 23 may include monocrystalline silicon having P-type impurities. The P-type impurities may include B, BF, BF₂ or a combination thereof. The isolation layer 25 may include a single layer or multiple layers. The isolation layer 25 may include at least two selected from the group consisting of Si, O, N, C and H. The isolation layer 25 may include silicon oxide, silicon nitride, silicon oxynitride, low-k dielectric, high-k dielectric or a combination thereof.

In an embodiment, the isolation layer 25 may include an insulating liner 26 and a buried insulating layer 27. The insulating liner 26 may include a single layer or multiple layers. The insulating liner 26 may include an oxide layer and a nitride layer on the oxide layer. The buried insulating layer 27 may include silicon oxide or low-k dielectric.

The plurality of the word line structures may be formed to cross the plurality of the active regions 23 and the isolation layer 25. The plurality of the word line structures may be buried in the plurality of the active regions 23 and the isolation layer 25. In the third direction VD, the upper surfaces of the plurality of the word line structures may be formed at a lower level than the upper surfaces of the plurality of the active regions 23 and the upper surface of the isolation layer 25. Each of the plurality of the word line structures may correspond to a buried gate or a buried word line. The gate dielectric layer 32 may be formed between the plurality of the word line structures and the plurality of the active regions 23 and between the plurality of the word line structures and the isolation layer 25. The gate capping layer 34 may cover the plurality of the word line structures.

The gate dielectric layer 32 may include silicon oxide, silicon nitride, silicon oxynitride, high-k dielectric or a combination thereof. The plurality of the word lines WL may include a conductive material such as metal, metal oxide, metal nitride, metal silicide, polysilicon, conductive carbon or a combination thereof. The gate capping layer 34 may include silicon oxide, silicon nitride, silicon oxynitride, low-k dielectric, high-k dielectric or a combination thereof.

The plurality of source/drain regions 36 may be formed in the plurality of the active regions 23 adjacent to the plurality of the word line structures. In an embodiment, the plurality of the source/drain regions 36 may include monocrystalline silicon having N-type impurities. The N-type impurities may include P, As, or a combination thereof.

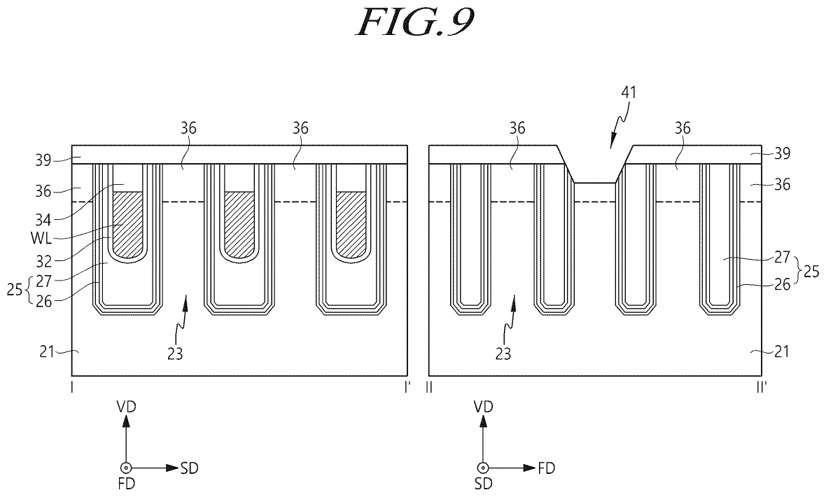

Referring to FIGS. 6 and 9, an interlayer insulating layer 39 may be formed to cover the isolation layer 25, the gate capping layer 34 and the plurality of source/drain regions 36. A first contact hole 41 which exposes a corresponding source/drain region among the plurality of source/drain regions 36 may be formed through the interlayer insulating layer 39. Forming the first contact hole 41 may include an anisotropic etching process. While the first contact hole 41 is formed, the upper surface of the corresponding source/drain region among the plurality of source/drain regions 36 may be etched and recessed downward. In an embodiment, the isolation layer 25 may be exposed on the sidewalls of the first contact hole 41. The interlayer insulating layer 39 may include silicon oxide, silicon nitride, silicon oxynitride, low-k dielectric, high-k dielectric or a combination thereof.

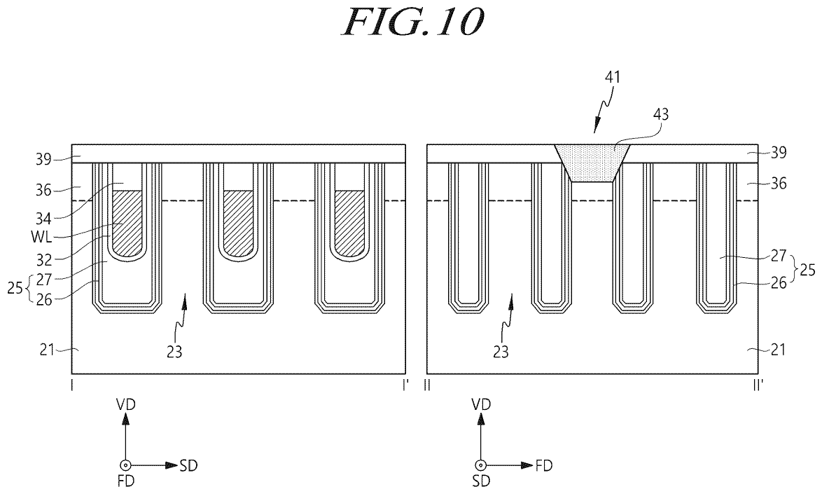

Referring to FIGS. 6 and 10, a bit plug 43 may be formed in the first contact hole 41. The bit plug 43 may contact a corresponding source/drain region 36. The bit plug 43 may include a conductive material such as metal, metal oxide, metal nitride, metal silicide, polysilicon, conductive carbon or a combination thereof.

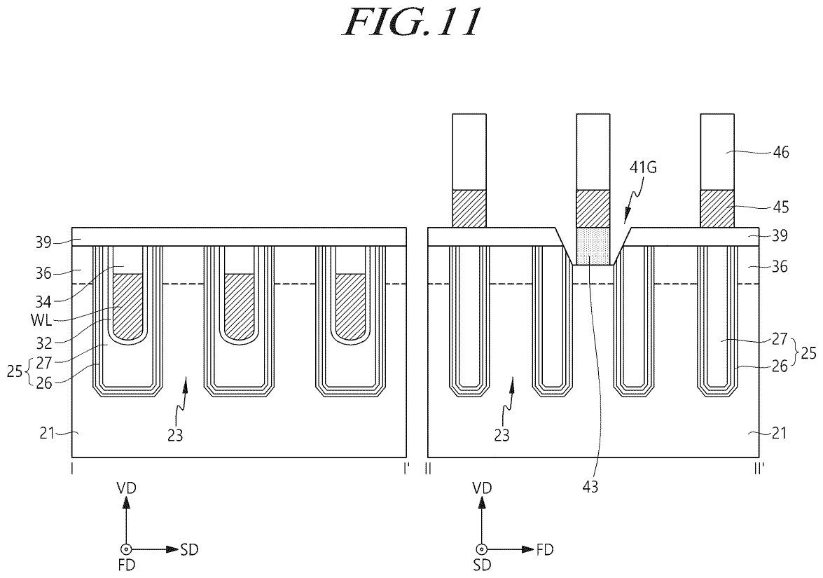

Referring to FIGS. 6 and 11, a plurality of bit lines 45 and a bit capping layer 46 may be formed on the interlayer insulating layer 39 and the bit plug 43. The bit capping layer 46 may cover the plurality of bit lines 45. Forming the plurality of bit lines 45 and the bit capping layer 46 may include a thin film forming process and a patterning process. The side surfaces of the plurality of the bit lines 45 may be vertically aligned with the side surfaces of the bit capping layer 46. Each of the side surfaces of the plurality of the bit lines 45 may form the same plane with a corresponding side surface among the side surfaces of the bit capping layer 46 in the third direction VD.

The bit plug 43 may contact the lower surface of a corresponding bit line among the plurality of bit lines 45. The bit plug 43 may be partially etched while the plurality of bit lines 45 are formed. The bit plug 43 may be limited to the bottom surface of the corresponding bit line among the plurality of bit lines 45. Gap regions 41G may be formed on both sides of the bit plug 43. The side surfaces of the bit plug 43 may be vertically aligned with the side surfaces of the plurality of bit lines 45.

Each of the plurality of bit lines 45 may extend in the second direction SD. The plurality of bit lines 45 may be formed parallel to each other in the first direction FD. The plurality of bit lines 45 may cross over the plurality of the active regions 23. Each of the plurality of bit lines 45 may cross over the plurality of the word line structures. Each of the plurality of bit lines 45 may be orthogonal to the plurality of the word line structures.

In an embodiment, a corresponding bit line among the plurality of bit lines 45 may cross each of the plurality of the active regions 23. The bit plug 43 may be formed at each of the intersections of the plurality of the active regions 23 and the plurality of bit lines 45.

The plurality of bit lines 45 may include a conductive material such as metal, metal oxide, metal nitride, metal silicide, polysilicon, conductive carbon or a combination thereof. The bit capping layer 46 may include a dielectric material such as silicon oxide, silicon nitride, silicon oxynitride, low-k dielectric, high-k dielectric or a combination thereof. In an embodiment, the bit capping layer 46 may include a nitride layer such as a silicon nitride layer.

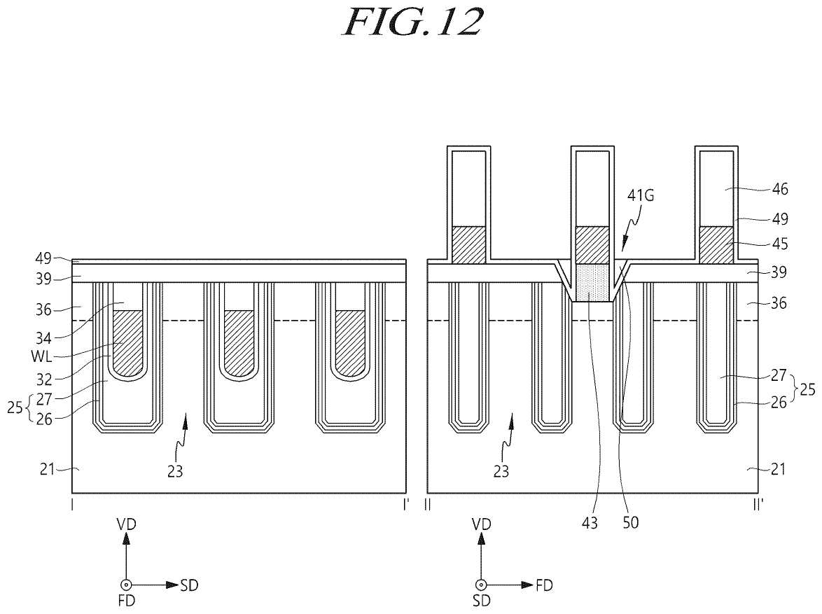

Referring to FIGS. 6 and 12, a first spacer 49 may be formed on the interlayer insulating layer 39, the bit plug 43, the plurality of bit lines 45 and the bit capping layer 46. The first spacer 49 may conformally cover the insides of the gap regions 41G. The first spacer 49 may cover the side surfaces of the bit plug 43, the plurality of bit lines 45 and the bit capping layer 46. A gap-fill spacer 50 may be formed on the first spacer 49 in the gap regions 41G. Forming the gap-fill spacer 50 may include a thin film forming process and an etch-back process. The gap-fill spacer 50 may fill the gap regions 41G.

Each of the first spacer 49 and the gap-fill spacer 50 may include a dielectric material such as silicon oxide, silicon nitride, silicon oxynitride, low-k dielectric, high-k dielectric or a combination thereof. Each of the first spacer 49 and the gap-fill spacer 50 may include SiO, SiCO, SiOCN, SiON or a combination thereof.

The gap-fill spacer 50 may include a material which has an etch selectivity with respect to the first spacer 49. The first spacer 49 may include a material which has an etch selectivity with respect to the bit capping layer 46. In an embodiment, the first spacer 49 may include low-k dielectric.

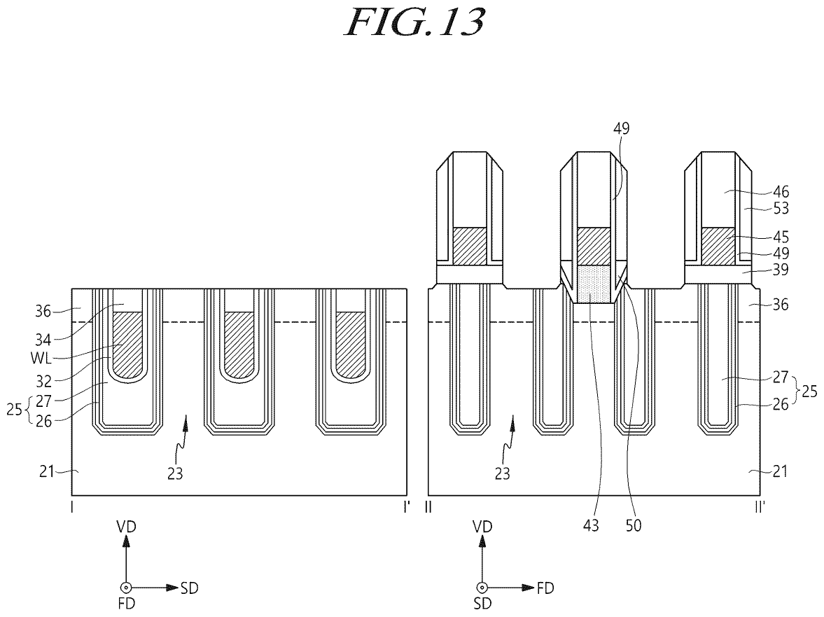

Referring to FIGS. 6 and 13, a second spacer 53 may be formed on the first spacer 49. Forming the second spacer 53 may include a thin film forming process and an anisotropic etching process. The second spacer 53 may be formed on the side surfaces of the plurality of bit lines 45 and the bit capping layer 46. While forming the second spacer 53, the first spacer 49 and the interlayer insulating layer 39 may be partially removed to expose the plurality of source/drain regions 36 and the isolation layer 25.

The first spacer 49 may be preserved between the side surfaces of the bit capping layer 46 and the second spacer 53, between the side surfaces of the plurality of bit lines 45 and the second spacer 53, between the upper surface of the interlayer insulating layer 39 and the second spacer 53, between the gap-fill spacer 50 and the bit plug 43, and between the gap-fill spacer 50 and the isolation layer 25. The first spacer 49 may include an L-shape. The upper surfaces of the plurality of source/drain regions 36 and the isolation layer 25 which are exposed outside the plurality of bit lines 45, the first spacer 49 and the second spacer 53 may be etched and recessed downward.

The second spacer 53 may include a dielectric material such as silicon oxide, silicon nitride, silicon oxynitride, low-k dielectric, high-k dielectric or a combination thereof. The second spacer 53 may include a material which has an etch selectivity with respect to the bit capping layer 46. In an embodiment, the second spacer 53 may include a material which has an etch selectivity with respect to the bit capping layer 46 and the first spacer 49. The second spacer 53 may include an oxide layer such as a silicon oxide layer.

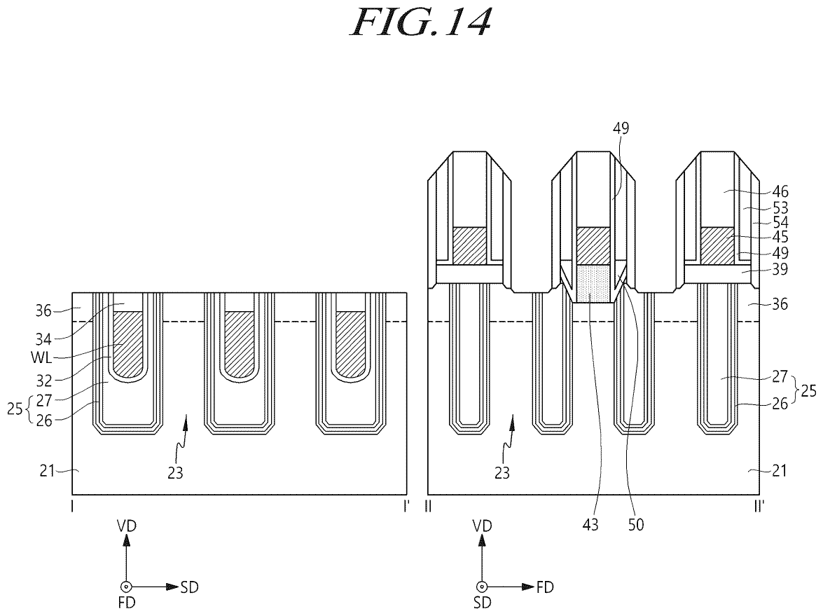

Referring to FIGS. 6 and 14, a third spacer 54 may be formed on the side surfaces of the second spacer 53 and the interlayer insulating layer 39. Forming the third spacer 54 may include a thin film forming process and an anisotropic etching process. The upper surfaces of the plurality of source/drain regions 36 and the isolation layer 25 which are exposed outside the plurality of bit lines 45, the first spacer 49, the second spacer 53 and the third spacer 54 may be etched and recessed downward.

The side surfaces of the third spacer 54 may contact the side surfaces of the second spacer 53, the side surfaces of the interlayer insulating layer 39 and the first spacer 49. The lowermost surface (or bottom surface) of the third spacer 54 may be formed at a lower level than the lower surface of the interlayer insulating layer 39 and the uppermost surface (or top surface) of the plurality of source/drain regions 36 in the third direction VD. The lower surfaces of the third spacer 54 may contact the plurality of source/drain regions 36 and the isolation layer 25.

The third spacer 54 may include a dielectric material such as silicon oxide, silicon nitride, silicon oxynitride, low-k dielectric, high-k dielectric or a combination thereof. The third spacer 54 may include SiO, SiCO, SiOCN, SiON or a combination thereof. The third spacer 54 may include a material which has an etch selectivity with respect to the second spacer 53 and the bit capping layer 46. In an embodiment, the third spacer 54 may include low-k dielectric.

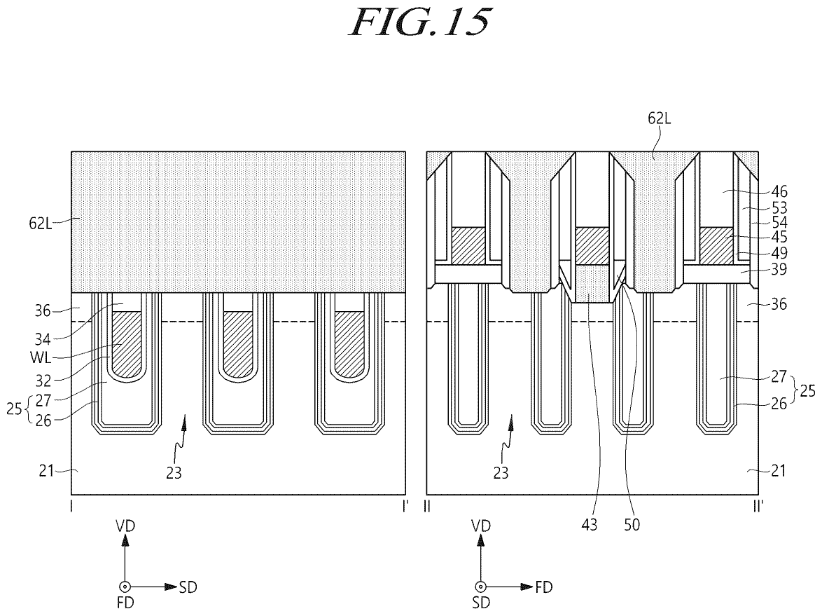

Referring to FIGS. 6 and 15, a lower contact layer 62L may be formed on the plurality of source/drain regions 36 and the isolation layer 25 which are exposed outside the plurality of bit lines 45, the first spacer 49, the second spacer 53 and the third spacer 54. The lower contact layer 62L may contact the plurality of source/drain regions 36. The lower contact layer 62L may include a conductive material such as metal, metal oxide, metal nitride, metal silicide, polysilicon, conductive carbon or a combination thereof. In an embodiment, the lower contact layer 62L may include a doped polysilicon layer.

Forming the lower contact layer 62L may include a thin film forming process and a planarization process. The planarization process for forming the lower contact layer 62L may include a chemical mechanical polishing (CMP) process, an etch-back process or a combination thereof. The upper surfaces of the lower contact layer 62L and the bit capping layer 46 may form substantially the same plane.

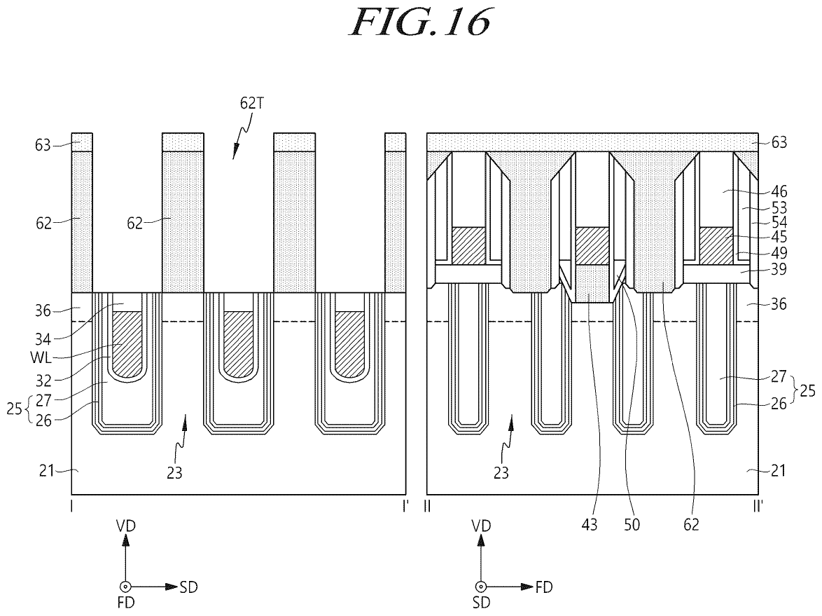

Referring to FIGS. 6 and 16, a mask pattern 63 may be formed on the lower contact layer 62L and the bit capping layer 46. A plurality of lower contact plugs 62 and a plurality of isolation trenches 62T may be formed by etching the lower contact layer 62L using the mask pattern 63 as an etch mask. The isolation layer 25 and the gate capping layer 34 may be exposed at the bottoms of the plurality of isolation trenches 62T. Each of the plurality of lower contact plugs 62 may contact a corresponding source/drain region among the plurality of source/drain regions 36.

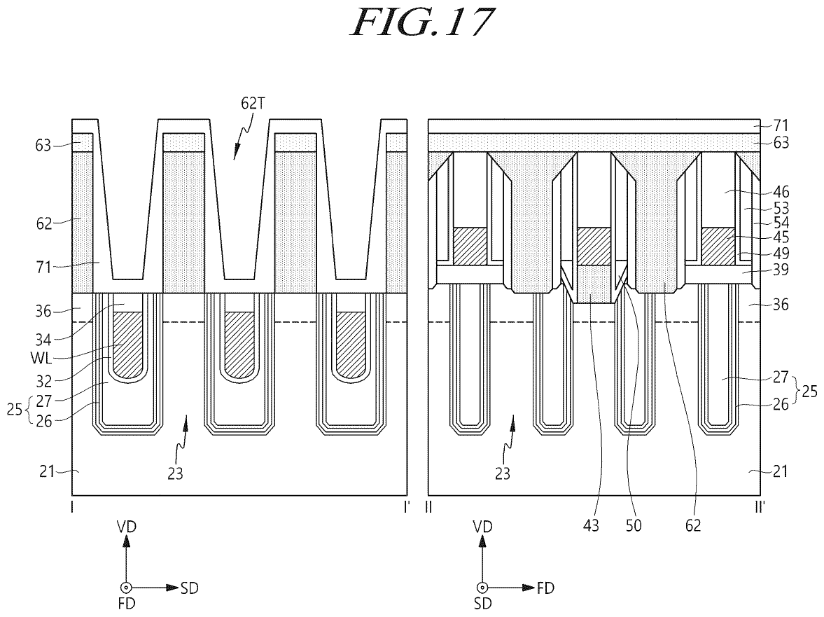

Referring to FIGS. 6 and 17, a tapered dielectric layer 71 may be formed in the plurality of isolation trenches 62T. Forming the tapered dielectric layer 71 may include an atomic layer deposition (ALD) process or a cyclic deposition process. The tapered dielectric layer 71 may include a material which has an etch selectivity with respect to the bit capping layer 46. In an embodiment, the tapered dielectric layer 71 may include oxide such as SiO, SiCO, SiON, SiOCN or a combination thereof.

In the plurality of isolation trenches 62T, the tapered dielectric layer 71 may be formed to be gradually thick in a downward direction. In an embodiment, the thickness of the tapered dielectric layer 71 in the second direction SD on the side surfaces of the plurality of lower contact plugs 62 may gradually increase from a top surface to a bottom surface in the third direction VD. Due to the formation of the tapered dielectric layer 71, the inner regions of the plurality of isolation trenches 62T may exhibit positive profiles. Due to the formation of the tapered dielectric layer 71, each of the remaining spaces of the plurality of isolation trenches 62T may show an inverted trapezoid shape in which a horizontal width gradually increases from a bottom surface to a top surface.

In an embodiment, forming the tapered dielectric layer 71 may include loading the substrate 21 having the plurality of lower contact plugs 62 and the plurality of isolation trenches 62T into a process chamber and repeatedly performing a tapered dielectric layer deposition cycle a multitude of times. The tapered dielectric layer deposition cycle may include sequentially supplying a first reaction gas on the substrate 21 in the process chamber, supplying a first purge gas into the process chamber, supplying a second reaction gas on the substrate 21 in the process chamber, supplying a second purge gas into the process chamber, supplying an inhibitor gas on the substrate 21 in the process chamber and supplying a third purge gas into the process chamber.

The first reaction gas may include dichlorosilane (DCS), hexachlorodisilane (HCDS), bis(diethylamino)silane (BDEAS) or a combination thereof. The second reaction gas may include N₂O, O₂, N₂, Ar, He, plasma thereof or a combination thereof. The inhibitor gas may include NH₃, NF₃, F₂, N₂, Ar, He, plasma thereof or a combination thereof. Each of the first to third purge gases may include inert gas such as argon, nitrogen, helium, neon or a combination thereof.

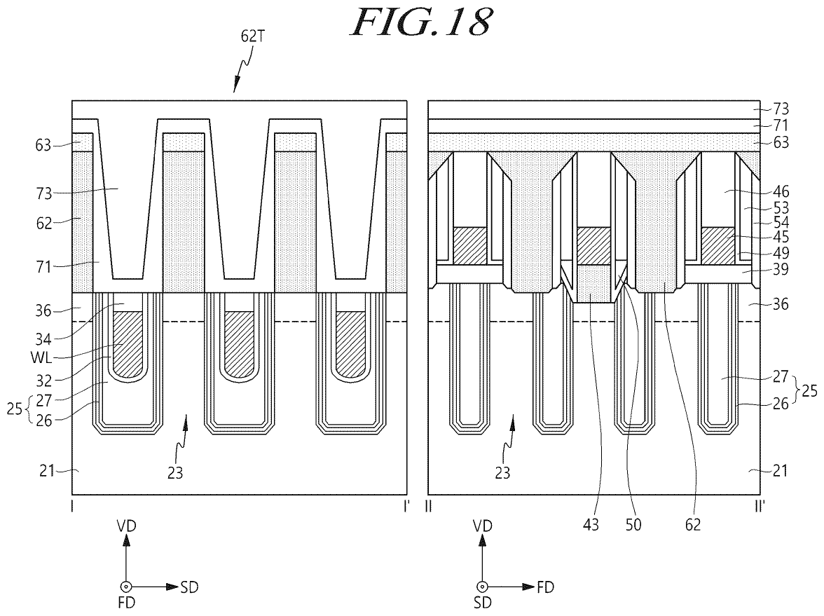

Referring to FIGS. 6 and 18, an isolation insulating layer 73 which fills the plurality of isolation trenches 62T may be formed on the tapered dielectric layer 71. The isolation insulating layer 73 may include a material which has an etch selectivity with respect to the tapered dielectric layer 71. In an embodiment, the isolation insulating layer 73 may include nitride such as silicon nitride. Due to the presence of the tapered dielectric layer 71, the isolation insulating layer 73 may densely fill the insides of the plurality of isolation trenches 62T. The tapered dielectric layer 71 may play a role of preventing a seam from being formed in the isolation insulating layer 73.

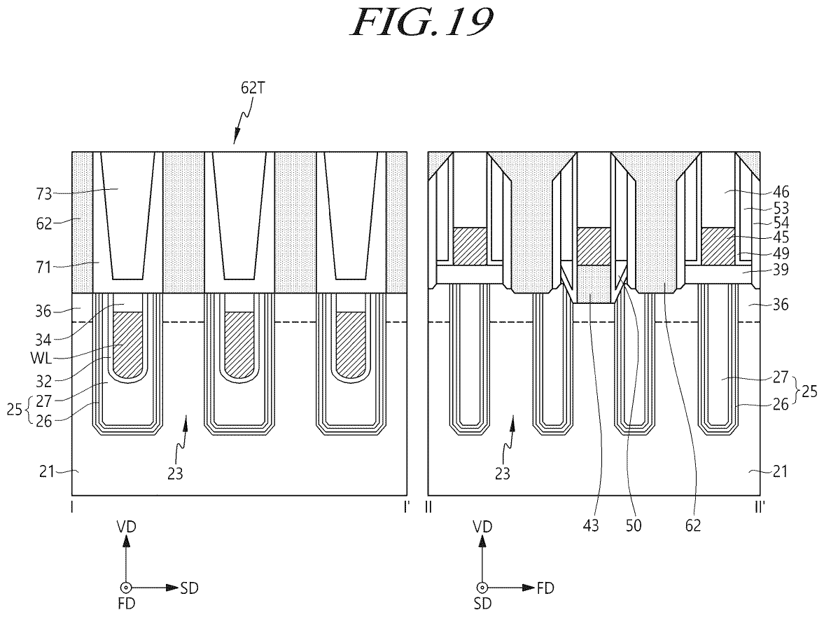

Referring to FIGS. 6 and 19, by using a planarization process, the upper surfaces of the bit capping layer 46, the plurality of lower contact plugs 62, the tapered dielectric layer 71 and the isolation insulating layer 73 may be exposed on the same plane. The planarization process may include a chemical mechanical polishing (CMP) process, an etch-back process or a combination thereof. While the planarization process is performed, the mask pattern 63 may be removed.

The tapered dielectric layer 71 and the isolation insulating layer 73 may be preserved in the plurality of isolation trenches 62T. The tapered dielectric layer 71 may be formed to surround the side surfaces and the lower surface of the isolation insulating layer 73. The isolation insulating layer 73 may show an inverted trapezoid shape whose horizontal width gradually increases from a bottom surface to a top surface.

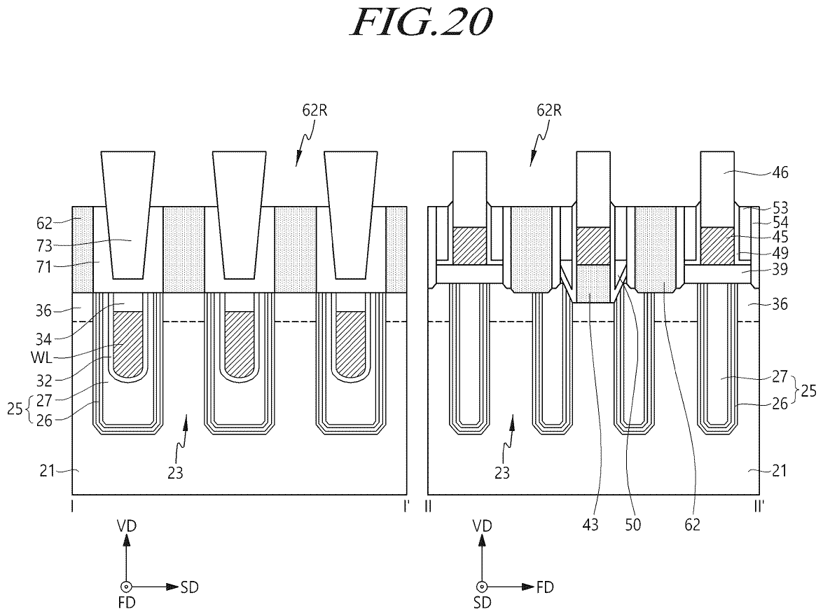

Referring to FIGS. 6 and 20, a plurality of recess regions 62R may be formed by removing the upper regions of the first spacer 49, the second spacer 53, the third spacer 54, the plurality of lower contact plugs 62 and the tapered dielectric layer 71. The upper surfaces of the first spacer 49, the second spacer 53, the third spacer 54, the plurality of lower contact plugs 62 and the tapered dielectric layer 71 may be formed at a lower level than the upper ends of the bit capping layer 46 and the isolation insulating layer 73 in the third direction VD. In an embodiment, the upper surfaces of the plurality of lower contact plugs 62 may be formed at a higher level than the upper surfaces of the plurality of bit lines 45 in the third direction VD. The side surfaces of the isolation insulating layer 73 and the bit capping layer 46 may be exposed in the plurality of recess regions 62R.

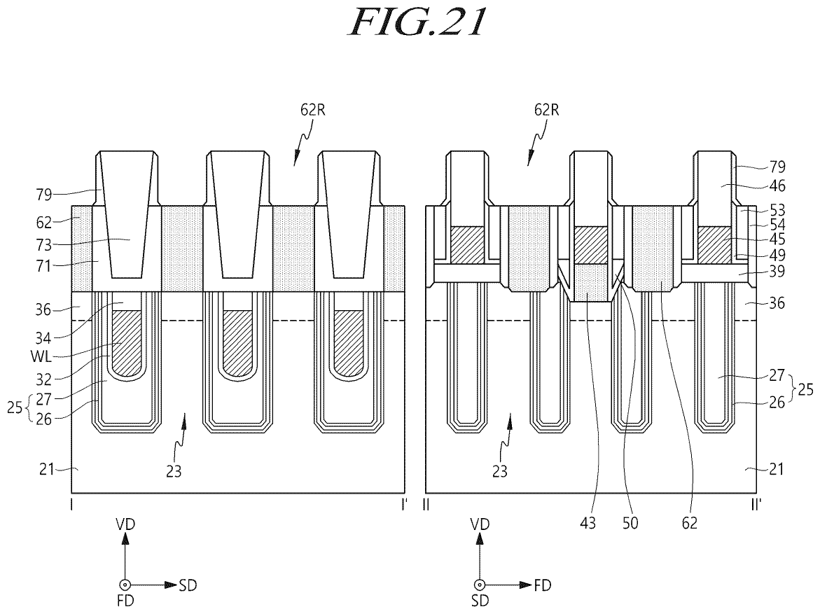

Referring to FIGS. 6 and 21, an upper spacer 79 may be formed on the side surfaces of the isolation insulating layer 73 and the bit capping layer 46. Forming the upper spacer 79 may include a thin film forming process and an anisotropic etching process. The plurality of lower contact plugs 62 may be exposed in the plurality of recess regions 62R. The upper spacer 79 may include silicon oxide, silicon nitride, silicon oxynitride, low-k dielectric, high-k dielectric or a combination thereof. In an embodiment, the upper spacer 79 may include nitride such as silicon nitride.

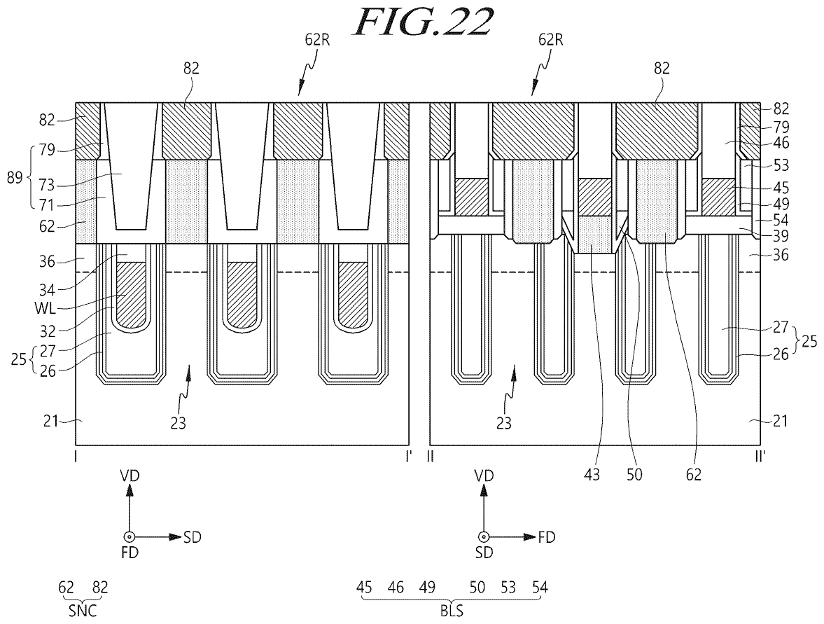

Referring to FIGS. 6 and 22, a plurality of upper contact plugs 82 may be formed in the plurality of recess regions 62R. Each of the plurality of the upper contact plugs 82 may contact a corresponding lower contact plug among the plurality of lower contact plugs 62. The plurality of upper contact plugs 82 may include a conductive material such as metal, metal oxide, metal nitride, metal silicide, polysilicon, conductive carbon or a combination thereof. In an embodiment, each of the plurality of upper contact plugs 82 may include a barrier layer and a metal layer on the barrier layer. In an embodiment, a metal silicide layer may be formed between the plurality of upper contact plugs 82 and the plurality of lower contact plugs 62, but will be omitted for the sake of simple description.

The plurality of bit lines 45, the bit capping layer 46, the first spacer 49, the gap-fill spacer 50, the second spacer 53 and the third spacer 54 may configure a plurality of bit line structures BLS. The plurality of lower contact plugs 62 and the plurality of upper contact plugs 82 may configure a plurality of storage node contacts SNC. The tapered dielectric layer 71, the isolation insulating layer 73 and the upper spacer 79 may configure a plurality of plug isolation patterns 89.

Referring again to FIG. 1, a plurality of memory elements 90 may be formed on the plurality of the storage node contacts SNC.

Although embodiments of the disclosed technology have been described for illustrative purposes, those skilled in the art will appreciate that various modifications, additions and substitutions are possible, without departing from the scope and spirit of the disclosed technology. Therefore, the embodiments disclosed above and in the accompanying drawings should be considered in a descriptive sense only and not for limiting the technological scope. The technological scope of the disclosed technology is not limited by the embodiments and the accompanying drawings. The spirit and scope of the disclosed technology should be interpreted in connection with the appended claims and encompass all equivalents falling within the scope of the appended claims. Furthermore, the embodiments may be combined to form additional embodiments.

What is claimed is:

1. A semiconductor device comprising:
a plurality of active regions delimited on a substrate;
a plurality of bit line structures crossing over the plurality of the active regions;
a plurality of storage node contacts disposed between the plurality of the bit line structures; and
a plug isolation pattern disposed between the plurality of the storage node contacts,
the plug isolation pattern comprising:
an isolation insulating layer disposed between the plurality of the storage node contacts; and
a tapered dielectric layer disposed between the isolation insulating layer and the plurality of the storage node contacts.

2. The semiconductor device according to claim 1, wherein the tapered dielectric layer surrounds a bottom and side surfaces of the isolation insulating layer.

3. The semiconductor device according to claim 1, wherein a horizontal width of the tapered dielectric layer gradually increases from a top surface to a bottom surface thereof.

4. The semiconductor device according to claim 1, wherein the isolation insulating layer includes an inverted trapezoid shape in which a horizontal width gradually increases from a bottom surface to a top surface.

5. The semiconductor device according to claim 1, wherein the isolation insulating layer includes a material which has an etch selectivity with respect to the tapered dielectric layer.

6. The semiconductor device according to claim 1, wherein the isolation insulating layer includes nitride, and the tapered dielectric layer includes oxide.

7. The semiconductor device according to claim 1,
wherein each of the plurality of the storage node contacts comprises:
a lower contact plug disposed on the plurality of the active regions; and
an upper contact plug disposed on the lower contact plug, and
wherein the tapered dielectric layer is disposed between the lower contact plug and the isolation insulating layer.

8. The semiconductor device according to claim 7, further comprising:
an upper spacer disposed on the tapered dielectric layer between the upper contact plug and the isolation insulating layer.

9. The semiconductor device according to claim 7, wherein
each of the plurality of the bit line structures comprises a bit line and a bit capping layer disposed on the bit line, and
an uppermost surface of the tapered dielectric layer is disposed at a higher level than an upper surface of the bit line.

10. The semiconductor device according to claim 9, wherein an uppermost surface of the tapered dielectric layer is disposed at a higher level than an upper surface of the lower contact plug.

11. The semiconductor device according to claim 9, wherein an upper surface of the tapered dielectric layer is recessed to a lower level than an upper surface of the lower contact plug.

12. The semiconductor device according to claim 1, further comprising:
a plurality of word lines crossing the plurality of the active regions, and intersecting with the plurality of the bit line structures,
wherein the plug isolation pattern overlaps with the plurality of word lines.

13. The semiconductor device according to claim 1, further comprising:
a plurality of memory elements disposed on the plurality of the storage node contacts,
wherein each of the plurality of memory elements includes a cell capacitor of a DRAM, a magnetic tunneling junction (MTJ) of an MRAM, a PRAM, an FRAM, an RRAM, or a combination thereof.

14. A semiconductor device comprising:
a plurality of interconnect structures disposed on a substrate and spaced apart from each other;
a plurality of contact plugs, each contact plug being disposed between a corresponding pair of adjacent interconnect structures; and
a plug isolation pattern disposed between the plurality of contact plugs,
wherein the plug isolation pattern comprises:
an isolation insulating layer disposed between the plurality of contact plugs; and
a tapered dielectric layer disposed between the isolation insulating layer and the plurality of contact plugs.

15. The semiconductor device according to claim 14, wherein a horizontal width of the tapered dielectric layer gradually increases from a top surface to a bottom surface thereof.

16. The semiconductor device according to claim 14, wherein the isolation insulating layer includes an inverted trapezoid shape in which a horizontal width gradually increases from a bottom surface to a top surface thereof.

17. The semiconductor device according to claim 14, wherein the isolation insulating layer includes nitride, and the tapered dielectric layer includes an oxide.
